(19) United States
(12) Patent Application Publication
(10) Pub. No.: US 2026/0214873 A1
(43) Pub. Date: Jul. 23, 2026

(54) RF Blocking Headphone Cover

(71) Applicant: Yoshihiro Shozen, Sedro Woolley, WA (US)

(72) Inventor: Yoshihiro Shozen, Sedro Woolley, WA (US)

(21) Appl. No.: 19/452,485

(22) Filed: Jan. 19, 2026

Related U.S. Application Data
(60) Provisional application No. 63/747,906, filed on Jan. 22, 2025.

(51) Int. Cl. H05K 9/00; H04R 1/10

(52) U.S. Cl. CPC H05K 9/0043; H04R 1/1008; H04R 1/1041; H04R 1/1091; H05K 9/009; H04R 2420/07

(57) ABSTRACT

An RF radiation blocking headphone cover is designed to reduce the user's exposure to RF radiation by 90% or greater. The RF radiation blocking headphone cover comprises a stretchable outer material and an RF blocking or attenuating liner composed of materials such as silver and elastic materials on the interior side. The cover is designed to fit over the earpads of over-the-ear headphones and headsets, with the RF attenuating liner positioned between the wireless transmitter and the user's head. RF exposure can be reduced without compromising the Bluetooth connectivity or sound quality of the headphones.

### CROSS-REFERENCE TO RELATED APPLICATION AND PRIORITY CLAIM

This application claims the priority and benefit of U.S. Provisional Patent Application No. 63/747,906, entitled “RF Blocking Headphone Cover” filed on Jan. 22, 2025, the contents of which are incorporated herein by reference in their entirety as if fully set forth herein and made part of the present U.S. Utility Patent Application for all purposes.

### BACKGROUND OF THE INVENTION

### Field of the Invention

The present invention relates to accessories for electronic devices, specifically to a stretchable cover for over-the-ear and on-ear headphones and headsets, incorporating a radio frequency (RF) electromagnetic field (EMF) blocking liner designed to reduce a user's exposure to RF radiation emitted by the headphones.

### Description of the Related Art

With the increasing use of wireless electronic devices, including Bluetooth headphones and headsets, concerns have been raised regarding the potential health risks associated with prolonged exposure to radio frequency (RF) radiation. While numerous electromagnetic field (EMF) protection products, such as EMF-blocking stickers and pendants, have become available, they typically address the material's properties rather than actual reduction in RF radiation exposure to the user. Just as a waterproof fabric can only protect from rain if applied correctly, RF blocking materials can only provide effective protection when applied with sufficient surface area and positioned between the user and the source. Currently, there are no solutions specifically designed to reduce RF radiation directed at a user (i.e., user's head) while using over-the-ear headphones. A need exists for a headphone accessory that effectively reduces RF radiation exposure to the head while maintaining the connectivity and performance of the headphones.

### SUMMARY OF THE INVENTION

An RF radiation blocking headphone cover comprising a stretchable outer layer designed to fit over an earcup or earpad of a headphone; an RF attenuating liner comprised of a conductive or metallized material configured to attenuate RF radiation emitted by a wireless transmitter of the headphone, affixed to the interior side of the cover, positioned between the wireless transmitter of the headphone and a user's head; and an attachment feature configured to retain the RF radiation blocking headphone cover on the earcup or earpad of the headphone.

An RF radiation blocking headphone cover comprising one or more layers, wherein at least one layer is an RF attenuating liner comprised of a conductive or metallized material configured to attenuate RF radiation emitted by a wireless transmitter of a headphone; and an attachment feature configured to retain the RF radiation blocking headphone cover on an earcup or earpad of the headphone.

An RF radiation blocking headphone cover comprising an RF attenuating liner comprised of a conductive or metallized material configured to attenuate RF radiation emitted by a wireless transmitter of a headphone, affixed to the interior side of the cover, positioned between the wireless transmitter of the headphone and a user's head such that RF radiation exposure is attenuated toward the user's head and maintaining wireless connectivity and sound quality of the headphone; and an attachment feature configured to retain the RF radiation blocking headphone cover on an earcup or earpad of the headphone.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a user with headphones and RF radiation blocking headphone covers;

FIG. 2 shows an inner view of an RF radiation blocking headphone cover;

FIG. 3 shows an outer view of an RF radiation blocking headphone cover;

FIG. 4 shows an isometric view of an RF radiation blocking headphone cover;

FIG. 5 shows an RF radiation blocking headphone cover 106 placed on a headphone 104;

FIG. 6 shows an isometric view of a stretched RF radiation blocking headphone cover;

FIG. 7 shows RF radiation attenuation without an RF radiation blocking cover and with an RF radiation blocking cover;

FIG. 8 shows RF radiation measurement of a headphone without RF radiation blocking headphone covers; and

FIG. 9 shows RF radiation measurement of a headphone with RF radiation blocking headphone covers.

### DETAILED DESCRIPTION

Described herein are stretchable covers for over-the-ear and on-ear headphones, featuring an RF blocking liner on the interior side of the cover. The RF blocking liner can be made from conductive materials such as silver, copper, nickel, carbon, or blends thereof, which reduce RF radiation while allowing sound to pass through. Using a stretchable outer fabric and elastic bands, the covers are designed to fit snugly over various sized earcups or earpads, with the RF blocking liner covering substantially the entire surface area of the earcup(s)/earpad(s) facing the user's head. This configuration ensures that the RF radiation emitted by the headphone is significantly reduced, specifically in the direction of the user's head, while leaving the outer side of the earpads uncovered, ensuring that Bluetooth connectivity remains unaffected.

Implementations provide for use of the RF blocking liner, which can reduce the user's RF radiation exposure. The implementations can offer an effective solution for users concerned about RF radiation, without affecting the functionality of wireless over-the-ear headphones. Headphones can include devices such as gaming and call center headsets that use wireless technology and earpads that either cover one or both ears.

Described herein are RF radiation blocking headphone covers used with various over-the-ear and on-ear headphone and headset models (collectively further referred to as headphones). The RF radiation blocking headphone covers are stretchable to fit snugly over earcups/earpads of the headphones and can be composed of two main layers: an outer material and an RF blocking liner.

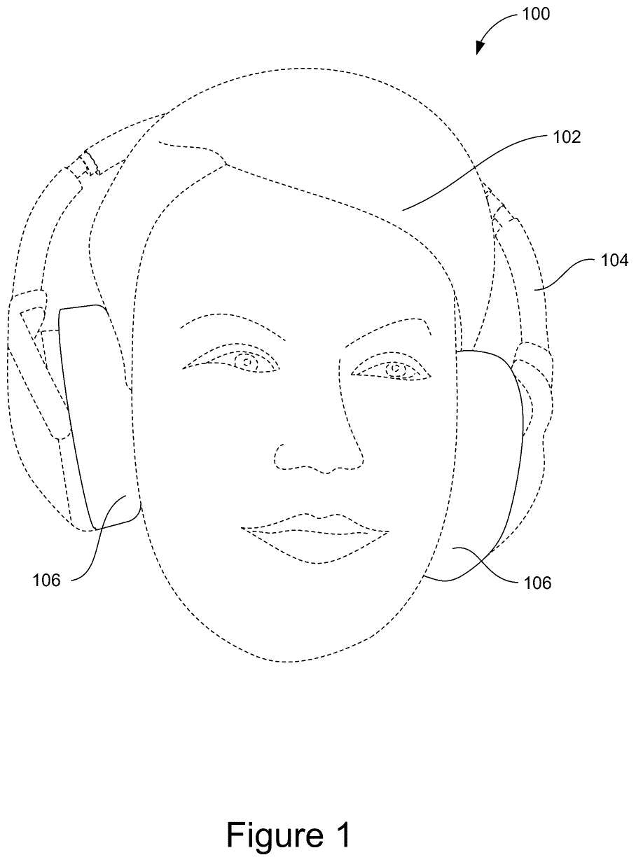

FIG. 1 illustrates a user with headphones and RF radiation blocking headphone covers. View 100 shows a user 102 wearing headphone 104. Headphone 104 can include various on-ear and over-ear headphones, on-ear and over-ear headsets, gaming headsets, call-center headsets, aviation headsets, etc. The headphone 104 can include earcups (not shown) or earpads (not shown). Earpads can be of various shapes including circular, oval, polygonal, or irregular shapes.

Implementations can provide for a wireless transmitter(s) (not shown) to be included in housing of the headphone 104 or earcup(s) or earpad(s). Such wireless transmitter(s) emit RF radiation. RF radiation blocking headphone covers 106 can be placed over the earcups/earpads to significantly reduce such RF radiation. RF radiation blocking headphone covers 106 include an RF attenuating liner further described herein that acts as a shield, significantly reducing the RF radiation emitted by the headphones (wireless transmitters) in the direction of the user 102 (i.e., head of user 102). The RF attenuating liner can cover substantially an entire inward-facing surface of the earpad.

The RF attenuating liner can be composed of one or more conductive materials affixed to the interior side of the RF radiation blocking headphone cover 106, positioned between wireless transmitter and the head of user 102 when the RF radiation blocking headphone covers 106 are applied to the earpads. An outer side of the earcups/earpads can remain uncovered by the RF attenuating liner to allow Bluetooth/wireless connectivity and sound quality.

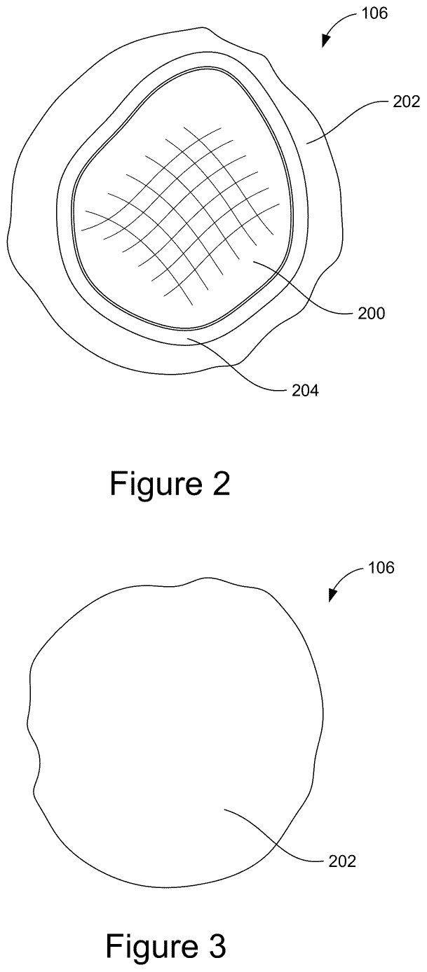

FIG. 2 illustrates an inner view of an RF radiation blocking headphone cover 106. Implementations provide for an inner RF attenuating liner 200 as discussed above and an outer layer 202. The RF radiation blocking headphone cover 106 can also include an attachment feature 204 to secure to the headphone 104 (earcups/earpads). Implementations provide for the attachment feature 204 to be an elastic band, drawstring, hook-and-loop fastener, snap, button, and/or combination of such.

The outer layer 202 can include materials such as nylon, polyester, or other durable and stretchable fabrics that allow sound to pass through. In certain implementations, the outer layer 202 can be omitted from the RF radiation blocking headphone cover 106, where only the RF attenuating liner 200 is used. In other words, the RF radiation blocking headphone cover 106 includes one layer, the RF attenuating liner 200.

The outer layer 202 can be used to provide better comfort, durability and color options. Implementations provide for the RF attenuating liner 200 to be attached to the stretchable outer layer 202 by stitching, adhesive bonding, lamination, weaving, knitting, or combinations thereof. Other implementations can provide for additional layers such as a cushioning or comfort layer positioned between the RF attenuating liner 200 and the outer layer 202. Further implementations can provide for the RF attenuating liner 200 to include multiple conductive layers or laminated conductive structures. The RF attenuating liner 200 can also include patterned perforations to enhance acoustic transparency.

Regardless of whether the RF radiation blocking headphone cover 106 includes one, two, or multiple layers, the RF radiation blocking headphone cover 106 should be stretchable, allowing it to fit snugly over different sizes and shapes of headphone earcups/earpads. The elasticity of the outer layer 202 along with attachment feature 204 ensures that the RF radiation blocking headphone cover 106 remains securely in place during use.

The RF attenuating liner 200 has high conductivity to attenuate RF radiation, porous to allow sound to pass through, and durable to withstand use. Examples of material/fabrics used include silver, copper, nickel, carbon, graphene or blends thereof, which reduce RF radiation while allowing sound to pass through. For example, the RF attenuating liner 200 can use silver coated nylon fabric. A silver coated nylon fabric provides the desired properties and also is found to be antimicrobial. A silver coated nylon fabric can provide over 50 dB attenuation (e.g., 99.999% reduction) over a range of 30 MHz to 3 GHz. The range of Bluetooth typically uses a frequency of 2.402 to 2.48 GHz. Silver coated nylon fabric is flexible and porous, allowing sound waves to pass through.

Silver coated nylon fabric can be electrically conductive. When an electromagnetic field (EMF) such as Bluetooth, Wi-Fi, cellular, etc. which creates RF radiation, is received by silver coated nylon fabric, reflection takes place. Free electrons in the silver move in response to the EMF, creating opposing fields that reflect incoming RF radiation, acting like a Faraday cage. RF radiation absorption and dissipation can also take place. Some energy can induce relatively small currents in the fabric, which is converted into negligible heat. The RF radiation wave loses strength as it passes through the fabric.

The fabric provides a conductive network that acts like a metal mesh. The openings in the fabric are smaller than EMF/RF radiation wavelengths. Therefore, an RF radiation wave cannot pass through the fabric. For example, Bluetooth (~2.4 GHz) has a wavelength of ~12.5 cm, and the fabric openings (pores) are thousands of times smaller. As to sound, and allowing sound to pass through the fabric, sound is related to air pressure waves. The fabric openings (pores) allow air to move through. The fibers of the fabric, such as nylon, are flexible and vibrate with sound waves. No electrical interaction is involved.

Therefore, opening or pore size of the fabric of the RF attenuating liner 200 provides a “frequency mismatch.” EMF/RF radiation wavelengths are centimeters to meters, are sensitive to conductive continuity, and can be blocked by the fine conductive mesh of the fabric. Sound waves wavelengths are millimeters to meters and can pass through structures that allow air movement.

FIG. 3 illustrates an outer view of an RF radiation blocking headphone cover 106. As discussed, the outer layer 202 can include materials such as nylon, polyester, or other durable and stretchable fabrics that allow sound to pass through. In certain implementations, the outer layer 202 can be omitted from the RF radiation blocking headphone cover 106, where only the RF attenuating liner 200 is used. The outer layer 202 can be used to provide better comfort, durability, and color options.

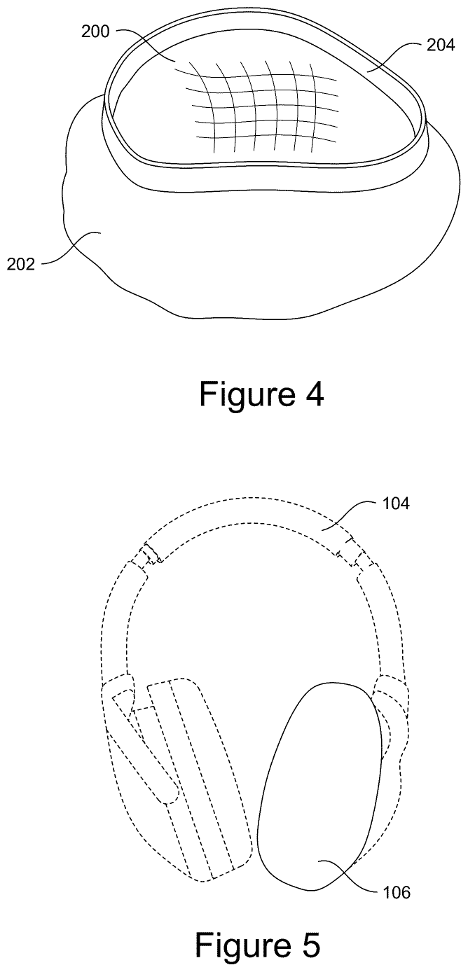

FIG. 4 illustrates an isometric view of an RF radiation blocking headphone cover 106. As described, implementations provide for the RF radiation blocking headphone cover 106 to include an inner RF attenuating liner 200, an outer layer 202, and an attachment feature 204.

FIG. 5 illustrates an RF radiation blocking headphone cover 106 placed on a headphone 104. As discussed, headphone 104 can include various on-ear and over-ear headphones, on-ear and over-ear headsets, gaming headsets, call-center headsets, aviation headsets, etc. The headphone 104 can include earcups or earpads (not shown). The earcups/earpads can be of various shapes including circular, oval, polygonal, or irregular shapes.

Implementations can provide for a wireless transmitter(s) (not shown) to be included in housing of the headphone 104 or earcup(s). Such wireless transmitter(s) emit RF radiation. RF radiation blocking headphone covers 106 can be placed over the earcups to significantly reduce such RF radiation. RF radiation blocking headphone covers 106 include an RF attenuating liner further described herein that acts as a shield, significantly reducing the RF radiation emitted by the headphones (wireless transmitters) in the direction of a user (e.g., head of user 102). The RF attenuating liner 200 can cover substantially an entire inward-facing surface of an earcup/earpad.

The RF attenuating liner 200 can be composed of one or more conductive materials affixed to the interior side of the RF radiation blocking headphone cover 106, positioned between wireless transmitter and the head of a user when the RF radiation blocking headphone covers 106 are applied to the earpads. An outer side of the earpads can remain uncovered by the RF attenuating liner 200 to allow Bluetooth/wireless connectivity and sound quality. The RF radiation blocking headphone cover 106 can also include an attachment feature (i.e., attachment feature 204) to secure to the headphone 104 earpads.

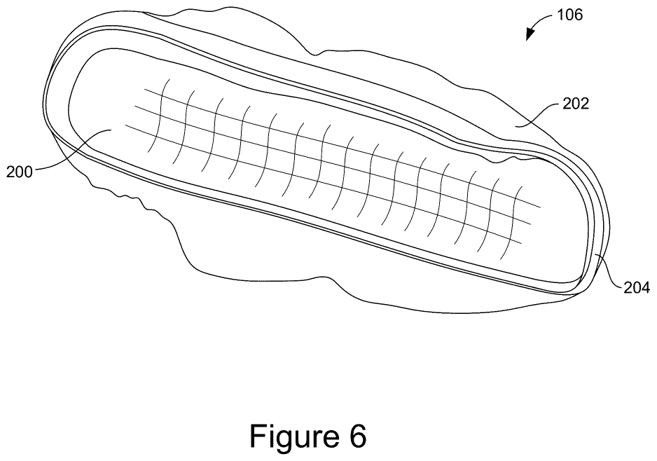

FIG. 6 illustrates an isometric view of a stretched RF radiation blocking headphone cover 106. RF radiation blocking headphone cover 106 should be stretchable, allowing it to fit snugly over different sizes and shapes of headphone earcups/earpads. The elasticity of the outer layer 202 along with attachment feature 204 ensures that the RF radiation blocking headphone cover 106 remains securely in place during use.

RF radiation reduction can be realized with the use of radiation blocking headphone cover 106. Assuming that the shield of radiation blocking headphone cover 106 full coverage in the direct line of sight of a wireless transmitter of headphone 104, reduction of RF radiation to the head of user 102 can be equal to the shielding capability of the RF attenuating liner 200.

An RF attenuating liner 200 with 20 dB attenuation shielding can reduce RF exposure by 99% to the user. Overall reduction, considering diffraction and reflections, might be slightly less. Additionally, a wireless transmitter may not always be directly aligned with the earcups/earpads, and slight off-center positioning can contribute to variations in diffraction and reflection. For example, with 5 cm diameter shielding coverage area, overall reduction can be around 90-99% depending on the position of the wireless transmitter.

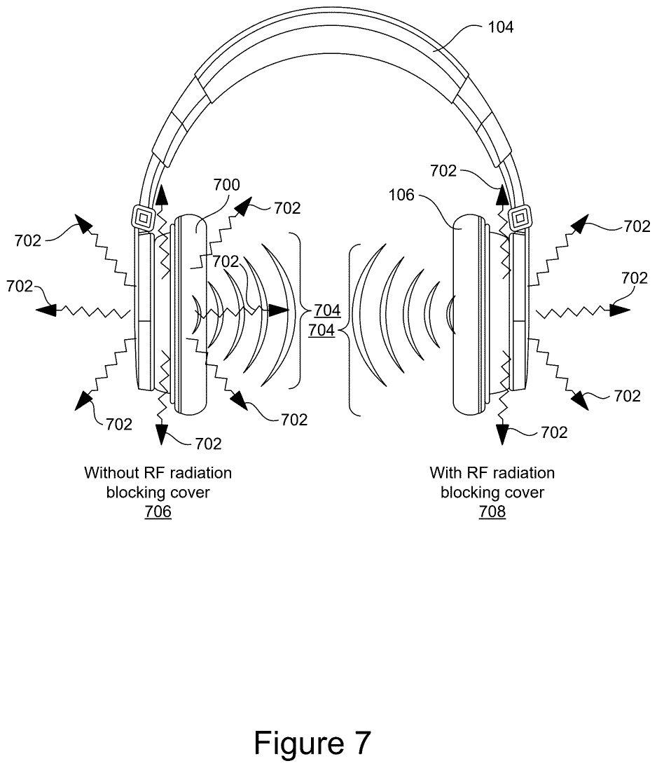

FIG. 7 illustrates RF radiation attenuation without an RF radiation blocking cover and with an RF radiation blocking cover. The headphone 104 includes earcups/earpads 700. As discussed, wireless transmitters (not shown) are part of the headphone 104. Wireless transmitters emit RF radiation represented as 702. The wireless transmitters also emit sound waves 704.

In an implementation without the RF radiation blocking cover 106, represented as 706. RF radiation 702 and sound waves 704 are emitted. In an implementation without the RF radiation blocking cover 106 represented as 708, only sound waves 704 are emitted.

As discussed, implementations can provide for consideration of the directional nature of RF attenuation, where the RF attenuating liner is positioned on the user-facing side of the earcups/earpads 700, reducing RF exposure toward a user's head while leaving the outward-facing side largely unshielded, to provide for wireless connectivity and sound quality.

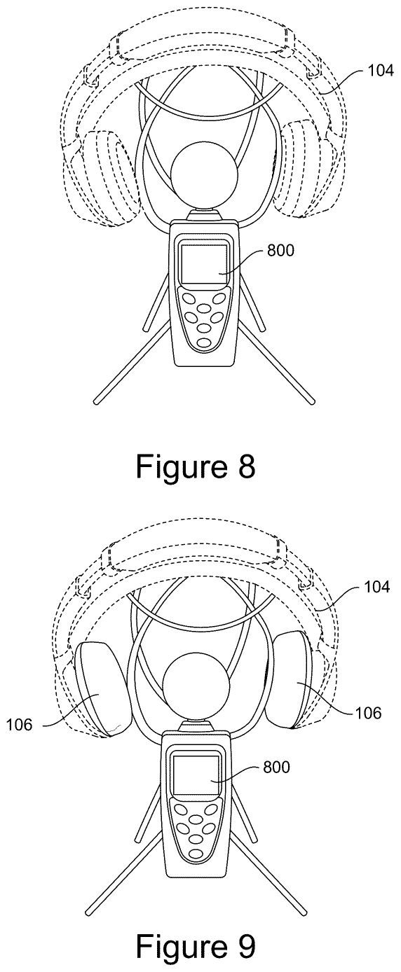

FIG. 8 illustrates RF radiation measurement of a headphone 104 without RF radiation blocking headphone covers. A headphone 104 is mounted on a rig to spread the headphones apart in order to simulate the headphone 104 being worn by a user 102. Examples of headphones can include Bluetooth enabled over the ear-the-ear headphones Sony model WM-1000XM4, Anker model Soundcore Q30, and the Nazusa model NA-NC01.

An RF meter 800 on fixed tripods is placed between the earcups/earpads of the headphone 104 with 4 cm on both sides. An example of RF meter 800 is the Tenmars model TM-195, capable of measuring electromagnetic field strength across a frequency range of 50 MHz to 3.5 GHz, which encompasses the frequencies used by wireless headphones.

Measurement is performed based on measured watts per square centimeter (W/cm²), recorded over a one-minute average. Example values measured without RF radiation blocking headphone covers for the Sony model WM-1000XM4 can be 2.748 W/cm², for the Anker model Soundcore Q30 can be 8.547 W/cm², for the Nazusa model NA-NC01 can be 1.431 W/cm².

FIG. 9 illustrates RF radiation measurement of a headphone with RF radiation blocking headphone covers 106. The same setup described in FIG. 8 is used in FIG. 8. Example resulting measured values with the use of RF radiation blocking headphone covers 106 can be as follows. For the Sony model WM-1000XM 4 can be 0.166 W/cm², showing an RF radiation reduction of 93.96%. For the Anker model Soundcore Q30 can be 0.157 W/cm², showing an RF radiation reduction of 98.16%. For the Nazusa model NA-NC01 can be 0.113 W/cm², showing an RF radiation reduction of 92.10%.

The present invention provides a practical and effective means of reducing RF radiation exposure from wireless over-the-ear headphones and headsets, while preserving their functionality. The selective use of an RF blocking liner on the inside of the cover represents an approach to address the growing concern of RF radiation exposure.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. An RF radiation blocking headphone cover comprising:
a stretchable outer layer designed to fit over an earcup or earpad of a headphone;
an RF attenuating liner comprised of a conductive or metallized material configured to attenuate RF radiation emitted by a wireless transmitter of the headphone, affixed to the interior side of the cover, positioned between the wireless transmitter of the headphone and a user's head; and
an attachment feature configured to retain the RF radiation blocking headphone cover on the earcup or earpad of the headphone.

2. The RF radiation blocking headphone cover of claim 1, wherein the RF radiation blocking headphone cover is configured to reduce the RF radiation exposure by 90% or greater.

3. The RF radiation blocking headphone cover of claim 1, wherein the RF radiation blocking headphone cover is compatible with multiple headphones and headsets.

4. The RF radiation blocking headphone cover of claim 1, wherein the RF attenuating liner comprises a fabric that includes one of, or a blend of one of the following: silver, copper, nickel, carbon, or graphene.

5. The RF radiation blocking headphone cover of claim 1, wherein the RF attenuating liner is a fabric that provides a conductive network that acts like a metal mesh, with openings smaller than wavelengths of RF radiation.

6. The RF radiation blocking headphone cover of claim 1, wherein the RF attenuating liner is an electrically conductive silver coated nylon fabric.

7. The RF radiation blocking headphone cover of claim 1, wherein the outer layer and RF attenuating liner are attached to one another by one of the following: stitching, adhesive bonding, lamination, weaving, knitting, or combinations thereof.

8. An RF radiation blocking headphone cover comprising:
one or more layers, wherein at least one layer is an RF attenuating liner comprised of a conductive or metallized material configured to attenuate RF radiation emitted by a wireless transmitter of a headphone; and
an attachment feature configured to retain the RF radiation blocking headphone cover on an earcup or earpad of the headphone.

9. The RF radiation blocking headphone cover of claim 8 further comprising a stretchable outer layer attached to the RF attenuating liner.

10. The RF radiation blocking headphone cover of claim 8 further comprising a cushioning layer.

11. The RF radiation blocking headphone cover of claim 8, wherein the RF attenuating liner comprises fabric that includes one of, or a blend of one of the following: silver, copper, nickel, carbon, or graphene.

12. The RF radiation blocking headphone cover of claim 8, wherein the RF attenuating liner is a fabric the provides a conductive network that acts like a metal mesh, with openings smaller than wavelengths or RF radiation.

13. The RF radiation blocking headphone cover of claim 8, wherein the RF attenuating liner is an electrically conductive silver coated nylon fabric that provides 50 db attenuation.

14. The RF radiation blocking headphone cover of claim 8, wherein the RF attenuating liner is antimicrobial.

15. An RF radiation blocking headphone cover comprising:
an RF attenuating liner comprised of a conductive or metallized material configured to attenuate RF radiation emitted by a wireless transmitter of a headphone, affixed to the interior side of the cover, positioned between the wireless transmitter of the headphone and a user's head such that RF radiation exposure is attenuated toward the user's head and maintaining wireless connectivity and sound quality of the headphone; and
an attachment feature configured to retain the RF radiation blocking headphone cover on an earcup or earpad of the headphone.

16. The RF radiation blocking headphone cover of claim 15 further comprising a stretchable outer layer attached to the RF attenuating liner, designed to fit over an earcup or earpad of a headphone.

17. The RF radiation blocking headphone cover of claim 15, wherein the RF radiation blocking headphone cover allows sound to pass through.

18. The RF radiation blocking headphone cover of claim 15, wherein the RF attenuating liner is a fabric the provides a conductive network that acts like a metal mesh, with openings smaller than wavelengths or RF radiation.

19. The RF radiation blocking headphone cover of claim 15, wherein the RF attenuating liner is a fabric that provides RF radiation absorption and dissipation.

20. The RF radiation blocking headphone cover of claim 15, wherein the RF attenuating liner comprises a fabric that includes one of, or a blend of one of the following: silver, copper, nickel, carbon, or graphene.
